(19) United States
(12) Patent Application Publication
(10) Pub. No.: US 2019/0101420 A1
(43) Pub. Date: Apr. 4, 2019

(54) VIBRATION DETECTION APPARATUS

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Ryoji NINOMIYA, Kunitachi Tokyo (JP); Hirofumi OMOTE, Adachi Tokyo (JP); Hiroshi OTA, Misato Saitama (JP)

(21) Appl. No.: 15/903,921

(22) Filed: Feb. 23, 2018

(30) Foreign Application Priority Data
Oct. 2, 2017 (JP) 2017-192866

(51) Int. Cl. G01D 11/24; H05K 5/00; H05K 1/18

(52) U.S. Cl. CPC G01D 11/245; H05K 5/0008; H05K 1/147; H05K 1/181; H05K 1/189

(57) ABSTRACT

A vibration detection apparatus includes a casing, a vibration sensor within the casing, a circuit board within the casing, and a component on the circuit board. The component processes a signal from the vibration sensor. A flexible wiring member is within the casing and electrically connects the vibration sensor to the component. The flexible wiring member includes a pre-bent flexible portion that is between a first connection portion, connected to the vibration sensor, and a second connection portion, connected to the circuit board.

### CROSS-REFERENCE TO RELATED APPLICATION

This application is based upon and claims the benefit of priority from Japanese Patent Application No. 2017-192866, filed Oct. 2, 2017, the entire contents of which are incorporated herein by reference.

### FIELD

Embodiments described herein relate generally to a vibration detection apparatus.

### BACKGROUND

An apparatus that detects vibration using a vibration sensor attached to an object is known.

### DESCRIPTION OF THE DRAWINGS

FIG. 1 is a perspective view of a vibration detection apparatus according to an embodiment.

FIG. 2 is a cross-sectional view taken along II-II of FIG. 1.

FIG. 3 is a perspective view of a board assembly, a flexible printed wiring board, and a vibration sensor accommodated in a vibration detection apparatus according to an embodiment.

FIG. 4 is a perspective view of a base block in the vibration detection apparatus according to an embodiment.

FIG. 5 is a perspective view of a board assembly, a flexible printed wiring board, and a vibration sensor accommodated in a vibration detection apparatus according to a modification example.

### DETAILED DESCRIPTION

In general, according to one embodiment, a vibration detection apparatus includes a casing, a vibration sensor within the casing, a circuit board within the casing, a component on the circuit board, and a flexible wiring member within the casing. The component processes a signal from the vibration sensor. The flexible wiring member electrically connects the vibration sensor to the component on the circuit board. The flexible wiring member includes a pre-bent flexible portion between a first connection portion, directly connected to the vibration sensor, and a second connection portion, directly connected to the circuit board.

An example embodiment of a vibration detection apparatus and a modification of this example are described in the following with reference to the figures. However, it should be noted the specific details of these described example are not limitations.

In the figures, arrows indicating directions are shown for the sake of explanatory convenience. Directions X, Y, and Z are orthogonal to one another. Furthermore, in the figures, direction Di indicates a protrusion direction (longitudinal direction) of a protruding portion 13 from a base portion 12, and a direction Dj indicates a thickness direction of the protruding portion 13 (or a circuit board 31). The directions Di and Dj are orthogonal to each other.

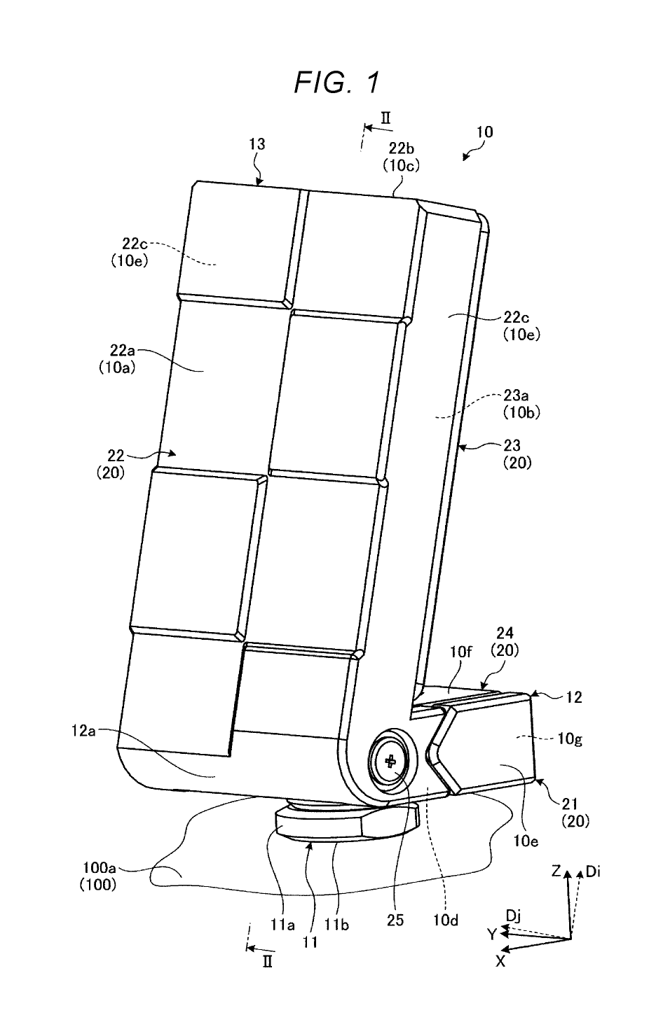

FIG. 1 is a perspective view of a vibration detection apparatus 10. As shown in FIG. 1, the vibration detection apparatus 10 includes an attachment 11, a base portion 12, and a protruding portion 13.

The attachment 11 has a fixed portion 11a that is fixed to a front surface 100a of an object 100, which is an object being tested or evaluated. The fixed portion 11a has a contact surface 11b intersecting the direction Z. The contact surface 11b is fixed to the front surface 100a by, for example, adhesive, whereby the attachment 11, and eventually the vibration detection apparatus 10, is fixed to the object 100. The attachment 11 could be referred to as “bracket”. The direction Z is an example of a first direction.

The base portion 12 is detachably connected to the attachment 11. The base portion 12 has a generally constant height in the direction Z. A shape of the base portion 12 is a flattened rectangular parallelepiped shape spreading to intersect the direction Z.

The base portion 12 and the protruding portion 13 are each configured into a generally L-shape or generally V-shape. The protruding portion 13 protrudes from an end portion 12a of the base portion 12 located on one longitudinal end thereof in such a manner as to be apart from the front surface 100a of the object 100. The protruding portion 13 is inclined with respect to the direction Z. That is, the protruding portion 13 is provided along the direction Di and inclined toward the base portion 12. An acute angle is formed between the directions Z and Di. That is, the direction Di is obliquely inclined with respect to the direction Z. In other words, an angle formed between the base portion 12 and the protruding portion 13 is an acute angle. The protruding portion 13 is of a flattened shape having a generally constant width and a generally constant thickness. A shape of the protruding portion 13 is a flattened rectangular parallelepiped shape extending to intersect the direction Dj. The direction Dj is orthogonal to the direction Di. A direction X is an example of a second direction.

The vibration detection apparatus 10 has a front surface 10a, a rear surface 10b, a top surface 10c, a bottom surface 10d, a side surface 10e, an upper surface 10f, and an end surface 10g. The front surface 10a is a surface of the protruding portion 13 orthogonal to the direction Dj. The rear surface 10b is another surface of the protruding portion 13 orthogonal to the direction Dj. The top surface 10c is a surface of the protruding portion 13 orthogonal to the direction Di. The bottom surface 10d is a surface orthogonal to the direction Z and is substantially parallel to the front surface 100a of the object 100. The side surface 10e is a side surface of the base portion 12 and the protruding portion 13 and is orthogonal to the direction Y. The upper surface 10f is an upper surface of the base portion 12 orthogonal to the direction Z and is generally parallel to the bottom surface 10d. The end surface 10g is a side surface of the base portion 12 and is orthogonal to the direction X.

The vibration detection apparatus 10 includes the casing 20. The casing 20 has a base block 21, a front case 22, a rear case 23, and a rear cover 24. The base block 21 forms a part of the side surface 10e and the end surface 10g. The base block 21 also forms a part of the base portion 12. The front case 22 has a front wall 22a, a top wall 22b, and a side wall 22c. The front wall 22a forms the front surface 10a. The top wall 22b forms the top surface 10c. In addition, the side wall 22c forms a part of the side surface 10e. The rear case 23 has a rear wall 23a. The rear case 23 forms a part of the protruding portion 13. The rear wall 23a forms the rear surface 10b. The rear cover 24 forms the upper surface 10f. The rear cover 24 forms a part of the base portion 12 and a part of the protruding portion 13. The casing 20 surrounds a space inside of which various components are accommodated.

The base block 21 is connected to the front case 22 by a connection device 25, such as a screw or a rivet.

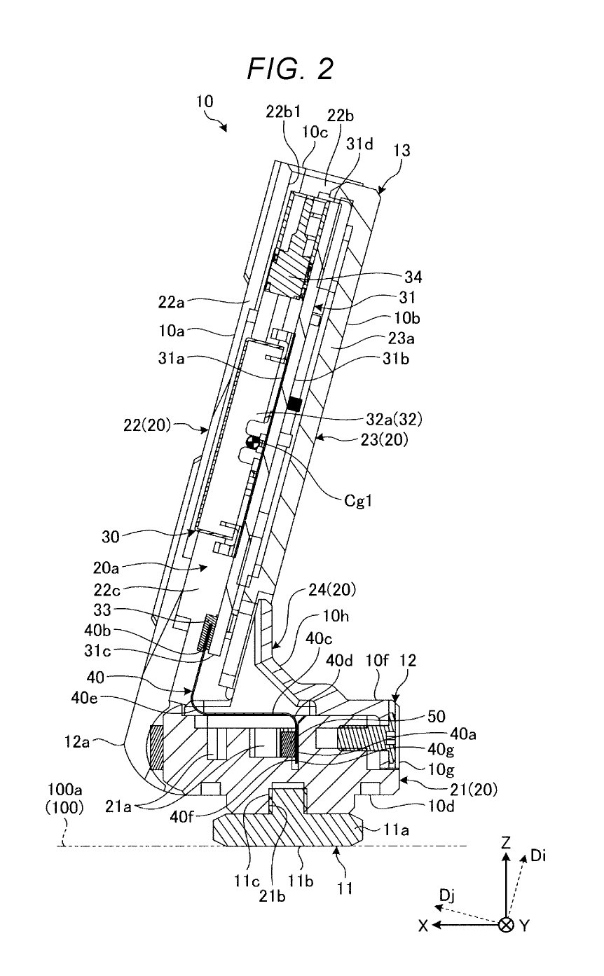

FIG. 2 is a cross-sectional view taken along II-II of FIG. 1. As shown in FIG. 2, the front wall 22a has a generally constant thickness along the direction Dj and extends along the directions Di and Y. The rear wall 23a is apart from the front wall 22a in the direction Dj, has a generally constant thickness along the direction Dj, and extends along the directions Di and Y. The top wall 22b has a generally constant thickness along the direction Dj and extends along the directions Di and Y. The rear cover 24 forms a boundary surface 10h that connects the rear surface 10b to the upper surface 10f. A thickness of the rear cover 24 is substantially equal to thicknesses of the front wall 22a, the rear wall 23a, the top wall 22b, and the side wall 22c. In addition, a thickness of the base block 21 along the direction Z is larger than the thicknesses of the front wall 22a, the rear wall 23a, and the top wall 22b.

Components, such as a board assembly 30, a flexible printed wiring board 40, and a vibration sensor 50, are accommodated in a chamber 20a surrounded by the front wall 22a, the rear wall 23a, the top wall 22b, the side wall 22c, the rear cover 24, and the base block 21.

Openings 21a that extend along the direction Z are provided in the base block 21. The openings 21a may be bottomed recess portions open into the chamber 20a or may be through-holes passing through the base block 21 generally along the direction Z.

The board assembly 30 has a circuit board 31, an amplification portion 32, a connector 33, and an external connection connector 34. The amplification portion 32, the connector 33, and the external connection connector 34 are fixed to the circuit board 31 by, for example, soldering.

The circuit board 31 has a generally constant thickness along the direction Dj and extends along the directions Di and Y. That is, the circuit board 31 is accommodated in the protruding portion 13 in a state of extending in a direction (the direction Di in the present embodiment) intersecting the contact surface 11b. It is noted that part of the circuit board 31 may also be accommodated in the base portion 12. The circuit board 31 is fixed to the rear wall 23a via a cushioning member that is not shown. The circuit board 31 has a front surface 31a that faces the front wall 22a and a rear surface 31b that faces the rear wall 23a. In addition, the circuit board 31 has an end portion 31c proximate to the base block 21 and an end portion 31d proximate to the top wall 22b.

The amplification portion 32 is mounted on the front surface 31a of the circuit board 31 in an intermediate portion thereof in the direction Di between the end portions 31c and 31d. The amplification portion 32 is fixed to the circuit board 31 and covered with a cover 32a. The amplification portion 32 includes a circuit that amplifies a detection signal from the vibration sensor 50. The amplification portion 32 is an example of an electrical component that performs an amplification process on the detection signal of the vibration sensor 50, such an amplifier circuit.

The connector 33 is mounted on the front surface 31a of the circuit board 31 in the end portion 31c thereof. A second end portion 40b of the flexible printed wiring board 40 is inserted into and/or attached to the connector 33. A conductor in the connector 33 electrically connects an internal conductor of the flexible printed wiring board 40 to a conductor on the circuit board 31.

The external connection connector 34 is mounted on the front surface 31a of the circuit board 31 in the end portion 31d thereof. A through-hole 22b1, which is an opening, is provided in the top wall 22b on a side closer to the top surface 10c than the external connection connector 34. A connector passing through the through-hole 22b1 is attached to the external connection connector 34.

The flexible printed wiring board 40 has a plurality of wiring patterns formed thereon and an insulating layer that covers the wiring patterns. The flexible printed wiring board 40 is an example of a wiring member.

The flexible printed wiring board 40 is bent or bendable between a first end portion 40a and the second end portion 40b. The first end portion 40a is inserted into the opening 21a that is the bottomed recess portion extending along the direction Z within the base block 21. The first end portion 40a is fixed to the base block 21 by an adhesive, a sealant, or the like when inserted into the opening 21a. The vibration sensor 50 is mounted on the first end portion 40a. That is, surroundings of the vibration sensor 50 are covered with adhesive or sealant and fixed in an immovable manner within the opening 21a, and the adhesive or the sealant around the vibration sensor prevents vibration transmission to the vibration sensor 50. The first end portion 40a is an example of a first connection portion. The second end portion 40b is attached to the connector 33 and extends along the direction Di. The second end portion 40b is an example of a second connection portion. In a line of sight along the direction Y shown in FIG. 2, the direction Z in which the first end portion 40a extends obliquely intersects the direction Di in which the second end portion 40b extends. The direction Z in which the first end portion 40a extends is also an example of a third direction. It is noted that the first end portion 40a may extend in a direction different from the direction Z. The direction Di in which the second end portion 40b extends is an example of a fourth direction.

The flexible printed wiring board 40 exhibits flexibility and elasticity, and is provided in an elastically bent state between the first end portion 40a and the second end portion 40b. The flexible printed wiring board 40 can be bent into an S-shape or cranked in two portions, which are a first bent portion 40d between the first end portion 40a and an intermediate portion 40c and a second bent portion 40e between the intermediate portion 40c and the second end portion 40b. That is, the first bent portion 40d and the second bent portion 40e of the flexible printed wiring board 40 are bent in opposite directions. In this way, the flexible printed wiring board 40 includes the two bent portions (first bent portion 40d and second bent portion 40e) bent in the opposite directions.

Furthermore, gaps are left between the flexible printed wiring board 40 and the casing 20 (base block 21, front wall 22a, and rear cover 24) at least in the vicinity of the first bent portion 40d and the second bent portion 40e. That is, the flexible printed wiring board 40 is accommodated within the chamber 20a in a state in which the shape (a position, a curvature radius, and the like) of the flexible printed wiring board 40 is changeable for the first bent portion 40d and the second bent portion 40e.

The attachment 11 has the fixed portion 11a that has the contact surface 11b and a male connector portion 11c connected to the base block 21. The contact surface 11b intersects the direction Z. The fixed portion 11a is disk shaped and orthogonal to the direction Z. The male connector portion 11c protrudes from a central portion of the fixed portion 11a in the direction Z. A female connector portion 21b engaging with the male connector portion 11c is provided in the base block 21. The male connector portion 11c and the female connector portion 21b can also be referred to as “connection portions”. By rotating the female connector portion 21b, that is, the casing 20, with respect to the male connector portion 11c, it is possible to switch between a state in which the casing 20 is attached to the attachment 11 and a state in which the casing 20 is detached from the attachment 11.

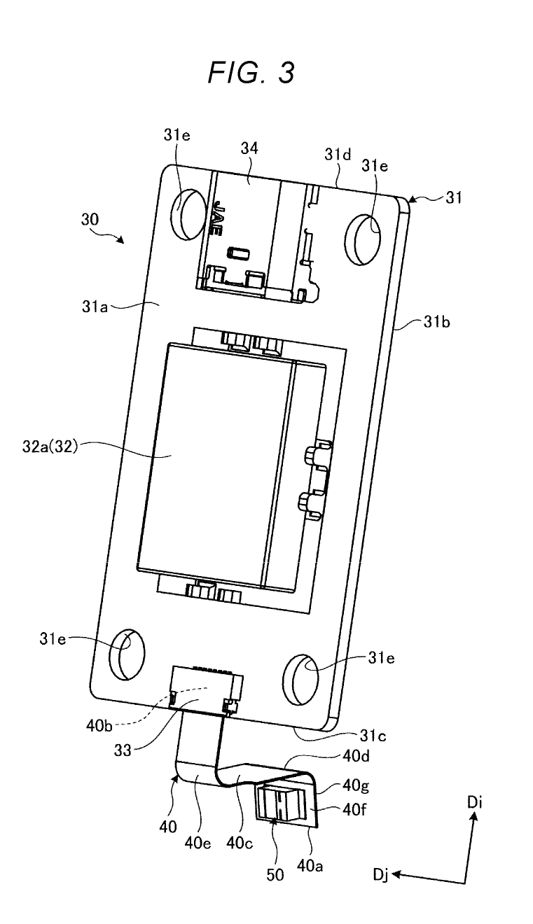

FIG. 3 is a perspective view of the board assembly 30, the flexible printed wiring board 40, and the vibration sensor 50. As shown in FIG. 3, the circuit board 31 is of a quadrangular (rectangular) plate shape. Through-holes 31e, through which connection devices, such as screws for fixing the circuit board 31 to the rear wall 23a can be passed, are provided in the four corners of the circuit board 31.

The cover 32a of the amplification portion 32 is of a flattened rectangular parallelepiped shape thin in the direction Di. The amplification portion 32 is located in a generally central portion of the front surface 31a of the circuit board 31.

The second end portion 40b of the flexible printed wiring board 40 is attached to the connector 33 by being inserted thereinto.

Moreover, the vibration sensor 50 is mounted on a front surface 40f of the flexible printed wiring board 40 by soldering or the like in the first end portion 40a of the flexible printed wiring board 40. Any of various types of sensors, for example, a piezoelectric vibration sensor, a MEMS (micro electro mechanical systems) vibration sensor, and a three-axis acceleration sensor can be adopted as the vibration sensor 50. It is noted that the vibration sensor 50 may be mounted on a surface 40g opposite to the front surface 40f.

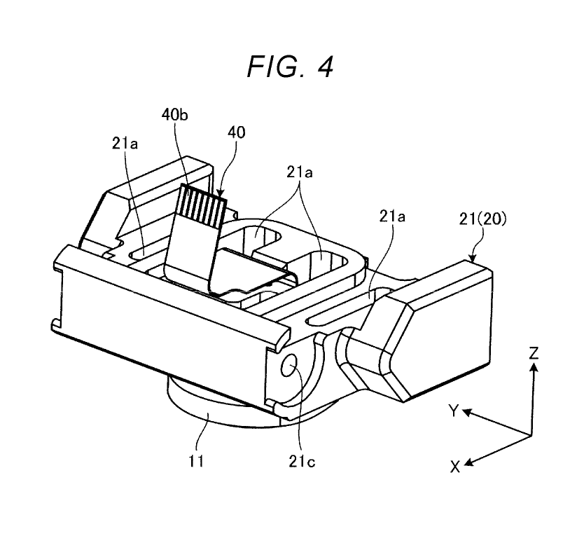

FIG. 4 is a perspective view of the base block 21. As shown in FIG. 4, the plurality of openings 21a, extending along the direction Z, is provided in the base block 21. In addition, a female connector portion 21c into which a male connector portion (not shown) of the connection device 25 can be inserted and is provided in the base block 21. The openings 21a prevent propagation of a vibration in the base block 21.

As described above, the flexible printed wiring board 40 is flexible, electrically connects the vibration sensor 50 to the circuit board 31, and is accommodated in the casing 20 in a state in which the first bent portion 40d and the second bent portion 40e have been bent but the bend state of the bent portions (40d and 40e) remain changeable. Thus, according to the present embodiment, even if a inertial vibration are generated in the board assembly 30, the vibrational force will be relaxed/counteracted by the bending of the first bent portion 40d and/or the second bent portion 40e in the flexible printed wiring board 40 and vibration is therefore difficult to transmit to the vibration sensor 50. Thus, it is possible to prevent, for example, the vibration due to the inertia of the board assembly 30 from influencing the vibration sensor 50. It should also be noted that the number of bent portions in the flexible printed wiring board 40 is not limited to two but may be just one or three or more.

Furthermore, according to the present embodiment, the protruding portion 13 accommodates the circuit board 31 in a posture of extending in the direction (direction Di) intersecting the contact surface 11b and protrudes from the base portion 12 in such a manner as to be apart from the contact surface 11b. Supposing that a region of the casing 20 in which the circuit board 31 is accommodated is configured to extend lengthwise along the object 100 in a state of being attached to the object 100, a relatively wide region will be required for attaching the vibration detection apparatus 10 to the front surface 100a of the object 100. In this respect, the vibration detection apparatus 10 can be attached to a narrower region on the front surface 100a of the object 100. Owing to this, it is advantageously possible to further increase a degree of freedom for an attachment position (detection position) of the vibration detection apparatus 10 and facilitate attaching the vibration detection apparatus 10 to a position at which vibration detection is necessary or a position more suited for the vibration detection.

Furthermore, according to the present embodiment, the protruding portion 13 protrudes in the direction Di inclined with respect to the direction Z (and the direction X). In other words, the protruding portion 13 protrudes from the base portion 12 toward the direction Di between the directions Z and X. Therefore, it is possible to make a center of gravity Cg1 (see FIG. 2) of the protruding portion 13 close to the contact surface 11b along the direction Z as compared to a configuration in which the protruding portion 13 protrudes along the direction Z. A moment arm of the base portion 12 at the center of gravity Cg1 with (a central portion in the direction X of) the contact surface 11b assumed as a fulcrum can be thereby made shorter. Therefore, it is possible to further reduce the vibration due to the inertia in the protruding portion 13 and eventually prevent the vibration due to the inertia in the protruding portion 13 from influencing the vibration detection by the vibration sensor 50. A narrower angle between the directions Di and Z is, for example, equal to or greater than 0° and equal to or smaller than 45°.

Furthermore, the protruding portion 13 protrudes from an end portion of the base portion 12 in the direction X toward the direction Di inclined with respect to the direction Z. Therefore, it is possible to make the center of gravity Cg1 (see FIG. 2) of the protruding portion 13 close to the contact surface 11b as compared to the configuration in which the protruding portion 13 protrudes from the central portion of the base portion 12 forward the direction Di. The moment arm of the base portion 12 at the center of gravity Cg1 with (the central portion in the direction X of) the contact surface 11b assumed as the fulcrum can be thereby made shorter. Therefore, it is possible to further reduce the vibration due to the inertia in the protruding portion 13 and eventually prevent the vibration due to the inertia in the protruding portion 13 from influencing the vibration sensor 50. It is noted that a position at which the protruding portion 13 protrudes from the base portion 12 is not limited to the end portion 12a of the base portion 12 in the direction X but may be displaced in the direction X from the central portion of the base portion 12 in the direction X. For example, the position may be a position between the end portion 12a and the central portion, a position between an end portion close to the end surface 10g and the central portion, or the end portion close to the end surface 10g. However, when the protruding portion 13 protrudes from the position between the central portion of the base portion 12 in the direction X and the end portion close to the end surface 10g or from the end portion close to the end surface 10g, the protruding portion 13 protrudes obliquely in a direction of approaching the central portion.

Furthermore, according to the present embodiment, the flexible printed wiring board 40 is accommodated in the casing 20 in a state of being elastically bent between the first end portion 40a and the second end portion 40b. Therefore, even if vibration is generated in the board assembly 30, the vibration is relaxed by an elastic deformation of the first bent portion 40d or the second bent portion 40e and does not easily propagate to the vibration sensor 50. It is noted that a wiring member exhibiting elasticity is not limited to a flexible printed wiring board.

Moreover, according to the present embodiment, the direction Z in which the first end portion 40a of the flexible printed wiring board 40, on which the vibration sensor 50 is mounted, extends and the direction Di in which the second end portion 40b of the flexible printed wiring board 40, which is connected to the circuit board 31, extends, for example, obliquely intersect each other. In the flexible printed wiring board 40, a vibration component in the direction in which the flexible printed wiring board 40 extends is easiest to transmit. Here, supposing that the direction in which the second end portion 40b, which is connected to the circuit board 31, extends is identical to the direction in which the first end portion 40a, to which the vibration sensor 50 is connected (or mounted), extends, thus there is a possibility that a relatively large vibration component will be transmitted from the second end portion 40b to the first end portion 40a and that the vibration due to the board assembly 30 will influence the vibration sensor 50. In this respect, the direction Z in which the first end portion 40a, on which the vibration sensor 50 is mounted, extends obliquely intersects the direction Di in which the second end portion 40b, which is connected to the circuit board 31, extends. Owing to this, a component, which is along the direction Z and results from orthogonal decomposition by an angle difference between the directions Z and Di, of a vibration in the direction Di input to the second end portion 40b, that is, a vibration smaller in amplitude than the vibration in the direction Di is transmitted to the first end portion 40a. According to the present embodiment, therefore, it is possible to prevent, for example, the vibration due to the inertia in the board assembly 30 including the circuit board 31 from influencing the vibration detection by the vibration sensor 50.

Moreover, the wiring member that electrically connects the circuit board 31 to the vibration sensor 50 is the flexible printed wiring board 40. Having a relatively thin flexible printed wiring board 40 permits the casing 20 and the vibration detection apparatus 10 to be configured more compactly.

Furthermore, the vibration sensor 50 can be mounted on the front surface 40f of the flexible printed wiring board 40. Therefore, it is possible to mount the vibration sensor 50 relatively easily and provide a vibration sensor 50 having a smaller and/or simpler configuration.

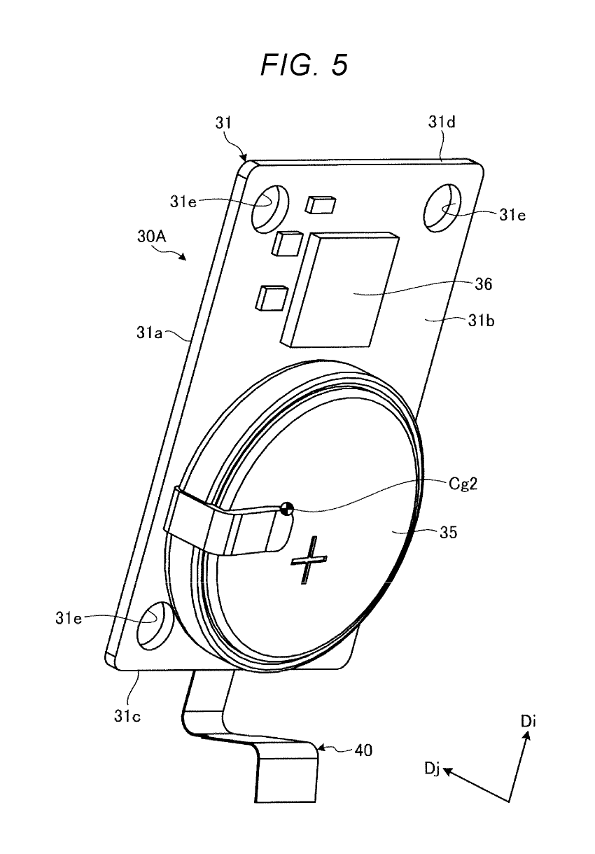

FIG. 5 is a perspective view of a board assembly 30A, the flexible printed wiring board 40, and the vibration sensor according to a modification of the above-described embodiment. As shown in FIG. 5, a relatively heavy component, such as a battery 35, is mounted on the rear surface 31b of the circuit board 31 at a position close to the end portion 31c that is closer to the contact surface 11b rather than the end portion 31d that is farther from the contact surface 11b. With such a configuration, a center of gravity Cg2 of the board assembly 30A, for example, can be positioned closer to the end portion 31c than to the end portion 31d and thus eventually closer to the contact surface 11b. According to the present modification, it is therefore possible to prevent the vibration due to the inertia in the protruding portion 13 from influencing the vibration sensor 50. In the this modification, a controller 36, such as an MCU (microcontroller unit), is mounted on the rear surface 31b of the circuit board 31. The controller 36 has not only an amplification function but also a function of obtaining an electrical signal or a detection value (e.g., data) from the detection signal. In addition, a nonvolatile memory could be mounted on the circuit board 31. In this case, the controller 36 can execute the writing of data to the nonvolatile memory and the reading of data from the nonvolatile memory. Moreover, the controller 36 can execute, for example, transmission and reception of data to and from an external apparatus via the external connection connector 34 (see FIGS. 2, 3, and the like). The controller 36 is an example of an electrical component that can perform various processes on the detection signal. It is noted that the battery 35 may also be accommodated in, for example, the base portion 12 (base block 21) separately from the circuit board 31.

While an example embodiment and a modification of the example embodiment have been described, have been presented by way of explanation only, and are not intended to limit the scope of the present disclosure. Indeed, the novel aspects described herein may be embodied in a variety of other forms; furthermore, various omissions, substitutions and changes in the form of the may be made without departing from the spirit of the present disclosure. The accompanying claims and their equivalents are intended to cover such forms or modifications as would fall within the scope and spirit of the present disclosure. Furthermore, the configurations and forms of each embodiment and each modification can be embodied while being partially interchanged. Moreover, the embodiment and the modification can be embodied while appropriately changing specifications such as each configuration or form (a structure, a type, a direction, a form, a magnitude, a length, a width, a thickness, a height, the number, an arrangement, a position, a material, and the like).

For example, the wiring member of an embodiment is not limited to a flexible printed wiring board 40 but may be another type of wiring member that exhibits flexibility (plasticity) such as a flexible flat cable, a ribbon cable, or a plurality of cables.

What is claimed is:

1. A vibration detection apparatus, comprising:
a casing;
a vibration sensor within the casing;
a circuit board within the casing;
a component on the circuit board for processing a signal from the vibration sensor; and
a flexible wiring member within the casing that electrically connects the vibration sensor to the component on the circuit board, the flexible wiring member including a pre-bent flexible portion between a first connection portion that is directly connected to the vibration sensor and a second connection portion that is directly connected to the circuit board.

2. The vibration detection apparatus according to claim 1, further comprising:
a contact surface connected to the casing for contacting an object for vibration testing or monitoring, wherein
the casing includes:
a base portion that accommodates the vibration sensor; and
a protruding portion that protrudes from the base portion in a direction of intersecting the contact surface, and at least a part of the circuit board is disposed on the protruding portion.

3. The vibration detection apparatus according to claim 2, wherein the protruding portion is provided obliquely with respect to a first direction that is orthogonal to the contact surface.

4. The vibration detection apparatus according to claim 3, wherein the base portion extends along a second direction orthogonal to the first direction, and the base portion and the protruding portion are provided in such a manner that an angle formed between the base portion and the protruding portion is an acute angle.

5. The vibration detection apparatus according to claim 1, wherein the bent portion of the flexible wiring member is flexible.

6. The vibration detection apparatus according to claim 5, wherein the first connection portion extends in a plane oblique to a plane in which the second connection portion extends.

7. The vibration detection apparatus according to claim 1, wherein the flexible wiring member is a flexible printed circuit board.

8. The vibration detection apparatus according to claim 7, wherein the vibration sensor is mounted on a front surface of the flexible printed circuit board to the first connection portion.

9. The vibration detection apparatus according to claim 1, wherein the flexible wiring member includes at least two bends along its length between the first and second connection portions.

10. The vibration detection apparatus according to claim 1, wherein the component is microcontroller unit.

11. The vibration detection apparatus according to claim 1, wherein the component includes an amplifier circuit.

12. The vibration detection apparatus according to claim 1, further comprising:
a battery mounted to the circuit board.

13. The vibration detection apparatus according to claim 1, wherein the component includes a battery.

14. The vibration detection apparatus according to claim 1, further comprising:
a battery mount on the circuit board by which a battery can be mounted to the circuit board.

15. A vibration sensor apparatus, comprising:
a base block;
a vibration sensor in the base block;
a circuit board disposed at an angle to base block;
a component on the circuit board for processing a signal from the vibration sensor;
a flexible printed circuit board electrically connecting the vibration sensor to the component on the circuit board, the flexible printed circuit board including a pre-bent flexible portion between a first connection portion that is directly connected to the vibration sensor and a second connection portion that is directly connected to the circuit board.

16. The vibration sensor apparatus according to claim 15, further comprising:
a casing surrounding the circuit board.

17. The vibration sensor apparatus according to claim 15, wherein the angle is less than 90°.

18. The vibration sensor apparatus according to claim 15, further comprising:
a surface attachment portion for attaching the base block to a surface, wherein
the base block and the surface attachment portion are connected by a screw portion.

19. The vibration sensor apparatus according to claim 15, wherein the component includes an amplifier.

20. The vibration sensor apparatus according to claim 15, wherein the flexible printed circuit board has an S-shape between the vibration sensor and the circuit board.
